(19) United States
(12) Patent Application Publication
(10) Pub. No.: US 2010/0103759 A1
(43) Pub. Date: Apr. 29, 2010

(54) POWER LINE DECODING METHOD FOR AN MEMORY ARRAY

(75) Inventors: PAUL OUYANG, Shanghai (CN); Zhi Li, Shanghai (CN); Qiang Huang, Shanghai (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Semiconductor Manufacturing International (Shanghai) Corporation, Shanghai (CN)

(21) Appl. No.: 12/491,126

(22) Filed: Jun. 24, 2009

(30) Foreign Application Priority Data
Oct. 24, 2008 (CN) 200810201786.8

(51) Int. Cl. G11C 5/14

(52) U.S. Cl. 365/226

(57) ABSTRACT

A method for selectively providing power supply voltage to a memory device. The method provides an integrated circuit memory device including a first plurality of memory cells. Each memory cell includes a power terminal and a ground terminal. The method includes selecting a second plurality of memory cells from the first plurality of memory cells. The method provides a first power voltage to the power terminal of each of the selected memory cells and a second power voltage to the power terminal of each of the unselected memory cells. The second power voltage is lower than the first power voltage. In an embodiment, the method applies a first ground voltage to the ground terminal of each of the selected memory cells and applies a second ground voltage to the ground terminal of each of the unselected memory cells. The second ground voltage is higher than the first ground voltage.

### CROSS-REFERENCES TO RELATED APPLICATIONS

This application claims priority to Chinese Patent Application No. 200810201786.8, filed Oct. 24, 2008, commonly assigned, incorporated by reference herein for all purposes.

### BACKGROUND OF THE INVENTION

The present invention is directed to integrated circuits and their processing for the manufacture of semiconductor devices. More particularly, the invention provides a method and device for selectively lowering power supply voltage to an SRAM memory array. Merely by way of example, the invention has been applied to SRAM devices for providing low power consumption while maintaining high memory speed. But it would be recognized that the invention has a much broader range of applicability. For example, the invention can be applied to other embedded or stand-alone integrated circuits memories, such as DRAM and non-volatile memories.

Integrated circuits or “ICs” have evolved from a handful of interconnected devices fabricated on a single chip of silicon to millions of devices. Current ICs provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of ICs. Semiconductor devices are now being fabricated with features less than a quarter of a micron across.

Increasing circuit density has not only improved the complexity and performance of ICs but has also provided lower cost parts to the consumer. An IC fabrication facility can cost hundreds of millions, or even billions, of dollars. Each fabrication facility will have a certain throughput of wafers, and each wafer will have a certain number of ICs on it. Therefore, by making the individual devices of an IC smaller, more devices may be fabricated on each wafer, thus increasing the output of the fabrication facility. Making devices smaller is very challenging, as each process used in IC fabrication has a limit. That is to say, a given process typically only works down to a certain feature size, and then either the process or the device layout needs to be changed. An example of such a limit is that memory cell standby current has become an major contributor to overall integrated circuits power consumption.

Fabrication of custom integrated circuits using chip foundry services has evolved over the years. Fabless chip companies often design the custom integrated circuits. Such custom integrated circuits require a set of custom masks commonly called “reticles” to be manufactured. A chip foundry company called Semiconductor International Manufacturing Company (SMIC) of Shanghai, China is an example of a chip company that performs foundry services. Although fabless chip companies and foundry services have increased through the years, many limitations still exist. For example, as logic devices are scaled and designed to operate under lower voltages, memory device leakage current makes it difficult to reduce overall device power consumption. Memory devices such as static random access memory (SRAM) consume substantial power in many integrated circuits applications. For example, the increasing demand for portable applications has made power consumption one of the most important design parameters. Many of these portable applications require a power efficient SRAM. These and other limitations will be discussed further below.

From the above, it is seen that an improved technique for designing semiconductor devices is desired.

### BRIEF SUMMARY OF THE INVENTION

According to the present invention, techniques directed to integrated circuits and their processing are provided for the manufacture of semiconductor devices. More particularly, the invention provides a method and device for selectively lowering power supply voltage to an SRAM memory array. Merely by way of example, the invention has been applied to SRAM devices for providing low power consumption while maintaining high memory speed. But it would be recognized that the invention has a much broader range of applicability. For example, the invention can be applied to other embedded or stand-alone integrated circuits memories, such as DRAM and non-volatile memories.

According to an embodiment of the invention, a method for providing a voltage supply in an integrated circuit memory device includes providing an integrated circuit memory device which includes a first plurality of memory cells. Each of the first plurality of memory cells includes a power terminal and a ground terminal. The method includes providing a first power voltage which is associated with a power supply. The method also provides a second power voltage which is lower than the first power voltage in magnitude. The method includes selecting a second plurality of memory cells from the first plurality of memory cells. The first plurality of memory cells includes the second plurality of memory cells and a third plurality of memory cells. The third plurality of memory cells are unselected. The method provides the first power voltage to the power terminal of each of the second plurality of memory cells. The method provides the second power voltage, which is lower than the first power voltage in magnitude, to the power terminal of each of the third plurality of memory cells. The method then performs at least a read operation and/or a write operation to at least one of the second plurality of memory cells.

In a specific embodiment of the invention, the method includes providing a first ground voltage and a second ground voltage. The second ground voltage is higher than the first ground voltage. The method then supplies the first ground voltage to the ground terminal of each of the selected memory cells, and supplies the second ground voltage to the ground terminal of each of the unselected memory cells. In an embodiment, each of the memory cells is an SRAM memory cell. In a specific embodiment, each of the memory cells includes a first and second cross-coupled branches. Each branch further includes a load device and a drive transistor connected in series. In an embodiment, the power terminal of each memory cell is electrically connected to the load device and the ground terminal is electrically connected to the drive transistor. In a specific embodiment, the load device is a PMOS transistor and the drive transistor is an NMOS transistor. In another embodiment, the load device is an NMOS transistor and the drive transistor is an NMOS transistor. In yet another embodiment, the load device is a resistor and the drive transistor is an NMOS transistor. In a specific embodiment, the first power voltage is about 1.2 volts. In an embodiment, the second power voltage is about 0.9 volts. In certain embodiments, the first ground voltage is about 0 volts. In some embodiments, the second ground voltage is about 0.3 volts. In a specific embodiment, providing the second power voltage further includes providing a level-shifting transistor and lowering the first power voltage by approximately a threshold voltage of the level-shifting transistor. In some embodiments, providing the second power voltage further includes providing a source follower circuit. In an embodiment, selecting the second plurality of memory cells further includes providing a word line in the memory device, and selecting the memory cells coupled to the word line. In an embodiment, selecting the second plurality of memory cells further includes providing a plurality of word line in the memory device, each word line being coupled to at least a memory cell, and providing a word line pre-decoder for selecting a second plurality of word lines. The method then selects the memory cells coupled to the second plurality of word lines. In a specific embodiment, the second plurality of word lines includes four word lines.

According to another embodiment of the invention, a method for providing voltage supply in a memory device includes providing an integrated circuit memory device comprising a first plurality of memory cells. Each memory cell includes a power terminal and a ground terminal. The method provides a first ground voltage and a second ground voltage which higher than the first ground voltage in magnitude. The method selects a second plurality of memory cells from the first plurality of memory cells. The first plurality of memory cells includes the second plurality of memory cells and a third plurality of memory cells which are unselected. The method provides the first ground voltage to the ground terminal of each of the second plurality of memory cells and the second ground voltage to the ground terminal of each of the third plurality of memory cells. The second ground voltage being higher than the first ground voltage in magnitude. The method then performs at least a read operation and/or a write operation to at least one of the second plurality of memory cells.

In an alternative embodiment of the invention, an integrated circuit memory device is provided. The memory device includes a first plurality of memory cells. Each memory cell includes a power terminal. The memory device includes a decoding circuit for at least selecting a second plurality of memory cells from the first plurality of memory cells and providing an output signal. The first plurality of memory cells includes the second plurality of memory cells and a third plurality of memory cells. The third plurality of memory cells are not selected by the decoding circuit. The memory device includes a switch circuit for supplying a first power voltage to the power terminal of each of the second plurality of memory cells and supplying a second power voltage to the power terminal of each of the third plurality of memory cells in response to the output signal of the decoding circuit. The first power voltage is provided by a first power supply. The second power voltage is provided by a second power supply. The second power voltage is lower than the first power voltage in magnitude.

In a specific embodiment, each of the first plurality of memory cells further includes a ground terminal, and he memory device also includes a second switch circuit for supplying a first ground voltage to the ground terminal of each of the second plurality of memory cells and supplying a second ground voltage to the ground terminal of each of the third plurality of memory cells in response to the output signal of the decoding circuit. The first ground voltage is provided by a third power supply. The second ground voltage is provided by a fourth power supply. The second ground voltage is higher than the first ground voltage in magnitude. In an embodiment, each of the memory cells is an SRAM memory cell. In some embodiments, each of the memory cells comprises a first and second cross-coupled branches. Each branch further includes a load device and a drive transistor connected in series. In certain embodiments, the power terminal of each memory cell is electrically connected to the load devices and the ground terminal is electrically connected to the drive transistors. In a specific embodiment, the load device is a PMOS transistor and the drive transistor is an NMOS transistor. In another embodiment, the load device is an NMOS transistor and the drive transistor is an NMOS transistor. In yet another embodiment, the load device is a resistor and the drive transistor is an NMOS transistor. In a specific embodiment, the first power voltage is about 1.2 volts. In an embodiment, the second power voltage is about 0.9 volts. In certain embodiments, the first ground voltage is about 0 volts. In some embodiments, the second ground voltage is about 0.3 volts. In a specific embodiment, the second power supply further includes a level-shifting transistor for lowering the first power voltage by about a threshold voltage of the level-shifting transistor. In some embodiments, the second power supply further includes a source follower circuit. In a specific embodiment, the memory device also includes a first plurality of word lines, each of the word lines being coupled to at least a memory cell. The device includes an input circuit for receiving an address signal. The decoding circuit selects a second plurality of word lines from the first plurality of word lines in response to the address signal. In an embodiment, the second plurality of word lines includes one word line. In another embodiment, the second plurality of word lines includes four word lines.

Numerous benefits are achieved using one or more features of the present invention. In a specific embodiment, the present invention can provide an SRAM array having reduced standby current by lowering the power supply voltage of inactive cells. In certain embodiments, the invention can provide full power supply to active memory cells to maintain operating speed of the memory array. Certain embodiments of the invention achieve simple design and low cost implementation by, for example, using existing decoding signals for selective power line supply. Depending upon the specific embodiment, the invention also provides a method that is implemented using conventional circuit design methodology and process technology. Depending upon the embodiments, one or more of these benefits may be achieved. These and other benefits are described throughout the present specification and more particularly below.

### BRIEF DESCRIPTION OF THE DRAWINGS

FIG. 1 is a schematic diagram of a conventional SRAM array;

FIG. 2 is a simplified schematic diagram of an SRAM array 200 according to an embodiment of the present invention;

FIG. 3 is a simplified schematic diagram of an SRAM array 300 according to an alternative embodiment of the present invention;

FIG. 4 is a simplified schematic circuit diagram of an SRAM memory cell for SRAM array 300 according to an embodiment of the present invention;

FIG. 5 is a simplified schematic diagram of an SRAM array 500 according to another embodiment of the present invention;

FIG. 6 is a simplified schematic circuit diagram of an SRAM memory cell for SRAM array 500 according to an embodiment of the present invention;

FIG. 7 is a simplified schematic diagram of an SRAM array 700 according to yet another alternative embodiment of the present invention;

FIG. 8 is a simplified schematic circuit diagram of an SRAM memory cell for SRAM array 700 according to an alternative embodiment of the present invention;

FIG. 9 is a simplified schematic circuit diagram of an address decoder for an SRAM device according to an embodiment of the present invention;

FIG. 10 is a simplified schematic circuit diagram of a power line decoder for an SRAM device according to an embodiment of the present invention; and

FIG. 11 is a simplified flow diagram of a method for providing voltage supply to an integrated circuit memory device according to an embodiment of the present invention.

### DETAILED DESCRIPTION OF THE INVENTION

According to the present invention, techniques directed to integrated circuits and their processing are provided for the manufacture of semiconductor devices. More particularly, the invention provides a method and device for selectively lowering power supply voltage to an SRAM memory array. Merely by way of example, the invention has been applied to SRAM devices for providing low power consumption while maintaining high memory speed. But it would be recognized that the invention has a much broader range of applicability. For example, the invention can be applied to other embedded or stand-alone integrated circuits memories, such as DRAM and non-volatile memories.

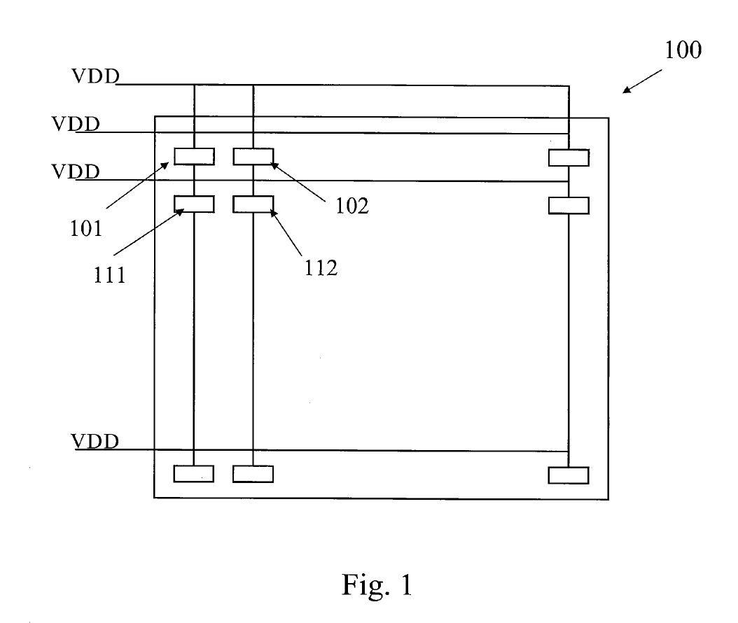

FIG. 1 is a schematic diagram of a conventional SRAM array 100. As shown SRAM memory array 100 includes memory cells, such as 101, 102, . . . , 111, 112, . . . , etc. In a typical conventional SRAM array, such as 100, all memory cells are supplied with the same power supply voltage VDD. The power grid in the array contains both horizontal and vertical VDD lines. According to an embodiment of the invention, memory cell standby current can be a major component of overall device power consumption. A method for reducing power consumption in a memory device is to decrease the power supply voltage (VDD) in the memory array which can reduce cell standby current. However, a lower power supply voltage can degrade the operating speed of the memory device. Therefore an improved technique is needed in memory device design.

Depending upon the embodiment, the present invention includes various features, which may be used. These features include the following:

1. Reduce SRAM array standby current by lowering the power supply voltage of inactive cells;

2. Supply full power supply to active memory cells to maintain operating speed of the memory array; and

3. Achieve simple design and low cost implementation by, for example, using existing address decoding signals for selecting power supply lines.

As shown, the above features may be in one or more of the embodiments to follow. These features are merely examples, which should not unduly limit the scope of the claims herein. One of ordinary skill in the art would recognize many variations, modifications, and alternatives. For example, certain embodiments discussed below refer to an SRAM memory array. However, one of ordinary skill in the art would recognize that the invention can be applied to other integrated circuit memory devices, such as DRAM, non-volatile memory devices, and read-only memory (ROM) devices, etc.

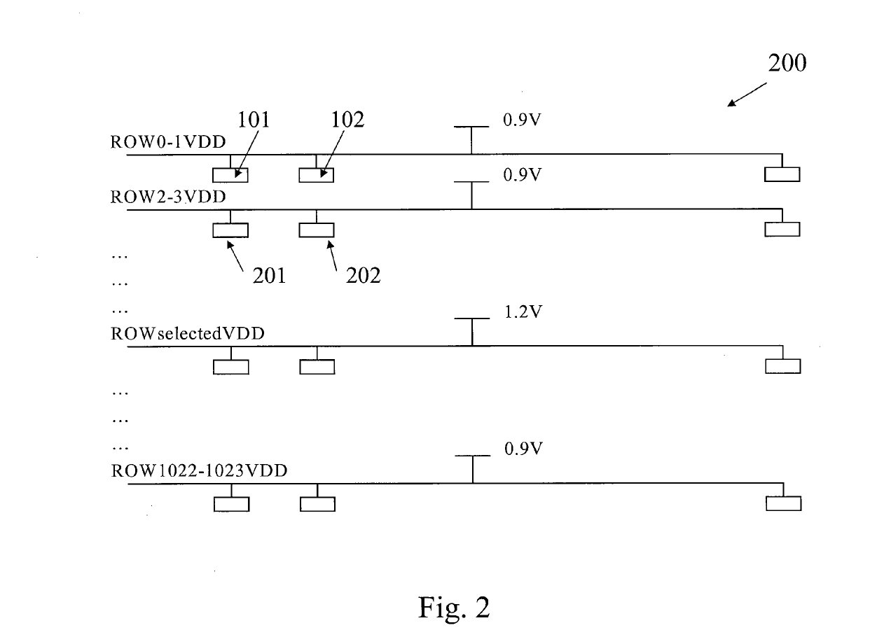

FIG. 2 is a simplified schematic diagram of an SRAM memory device 200 according to an embodiment of the present invention. This diagram is merely an example, which should not unduly limit the scope of the claims herein. One of ordinary skill in the art would recognize other variations, modifications, and alternatives. As shown, memory device 200 includes memory cells, such as 101, 102, . . . , 201, 202, . . . , etc. arranged in rows and columns. In a specific embodiment, every two rows of memory cells are coupled to a VDD power supply line. For example, in a particular embodiment, memory device 200 can include 1024 rows of memory cells, and memory cells in rows 0 and 1 are electrically connected to VDD power supply line marked as ROW0-1VDD in FIG. 2. Similarly, memory cells in rows 2 and 3 are electrically connected to VDD power supply line marked as ROW2-3VDD. Memory cells in rows 1022 and 1023 are electrically connected to VDD power supply line marked as ROW1022-1023VDD in FIG. 2. In an embodiment, for each memory operation, such as read or write, two rows are selected. For example, the selected rows in FIG. 2 are coupled to a power supply line ROWselectedVDD. In a preferred embodiment, the selected rows are provided with a power supply of 1.2 volts through power supply line ROWselectedVDD, whereas the unselected rows are provided with a reduced power supply voltage. For example, the reduced power supply voltage can be 0.9 volts. According to embodiments of the present invention, lowering power supply voltage to the unselected rows can substantially reduce the standby current of memory cells. This and other advantages are discussed further below.

In a specific embodiment, SRAM devices with an array size of 4 mega bits have been designed using a 0.13 um process. Merely as an example, an SRAM device is configured as 8 banks, with each bank having 512K bits. In a particular embodiment, a bank is internally organized in 1024 rows and 512 columns. In an embodiment, a single memory cell can have a standby current of 10 pA when the cell VDD voltage is 1.2V. A whole array containing 4M cells can consume a total standby current of about 40 mA. If the VDD is reduced to 0.9 volts, the cell current for a single memory cell can be reduced to about 0.01 pA. The standby current for the whole array can be reduced to about 40 uA. In this particular example, the power consumption using the lower power supply can be reduced to about 0.1% of the power consumption at the higher voltage supply. However, according to an embodiment, if the power supply to an entire SRAM memory array is reduced, the speed of the memory device can be degraded. According to an embodiment of the present invention, techniques are provided for selectively reducing power supply to inactive memory cells to reduce power consumption, while continuing full power supply in selected memory cells to maintain memory speed performance. Of course, one of ordinary skill in the art would recognize other variations, modifications, and alternatives.

In a specific embodiment, a memory device is designed with a power supply of 1.2 volts. The memory device can include a transistor having a threshold voltage Vt of, for example, 0.3 volts. In an embodiment, a lower power supply voltage of 0.9 volts can be obtained, for example, by using a voltage shifting circuit that produces an output voltage of 0.9 volts from an input voltage of 1.2 volts. In a specific embodiment, the voltage shifting circuit can be a source follower circuit including an NMOS transistor having a threshold voltage of 0.3 volts. With 1.2 volts applied at its gate terminal, a source terminal of the NMOS transistor is about 0.9 volts, approximately a Vt drop below the gate voltage. In alternative embodiment, other voltage shifting circuit can be used to generate a lower output voltage from a higher input voltage. Of course, one of ordinary skill in the art would recognize other variations, modifications, and alternatives.

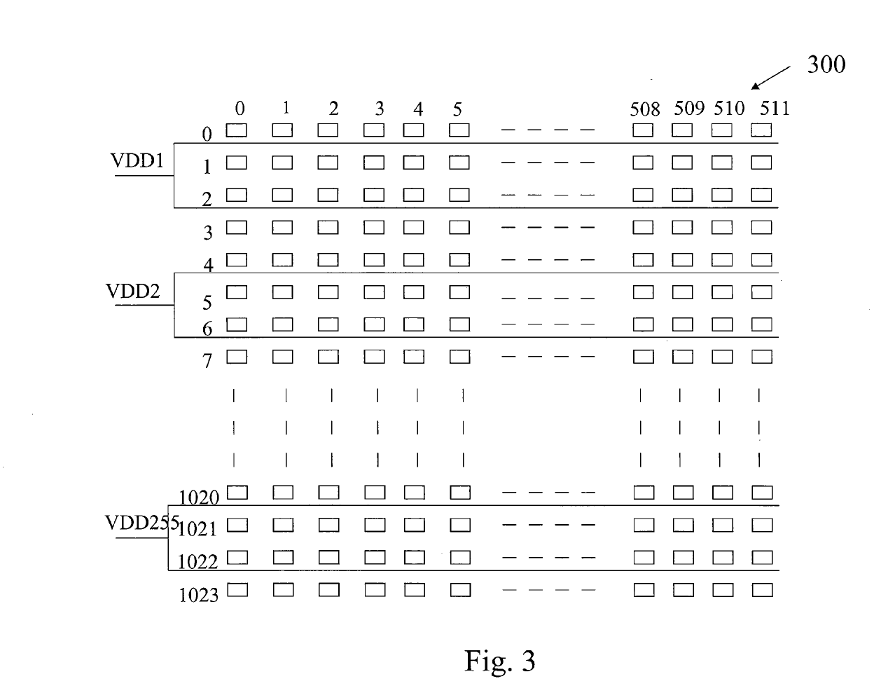

FIG. 3 is a simplified schematic diagram of an SRAM array device 300 according to an embodiment of the present invention. This diagram is merely an example, which should not unduly limit the scope of the claims herein. One of ordinary skill in the art would recognize other variations, modifications, and alternatives. As shown, memory device 300 includes memory cells arranged in 1024 rows and 512 columns. In a specific embodiment, every four rows of memory cells share a power voltage supply source. For example, rows 0-3 receive power supply from power supply source VDD via two power lines connected to VDD1. Similarly, rows 1020-10233 receive power supply from power supply source VDD via two power lines connected to VDD255. In an embodiment, four rows at a time are selected for a memory operation, such as read or write. The power supply voltage is raised to a higher voltage, e.g. 1.2 volts, for these selected rows, whereas the power supply voltage can be maintained at a lower voltage, e.g. 0.9 volts, for the unselected rows. Therefore, a reduction in memory array standby current can be achieved by embodiments of the present invention. Of course, there can be other variations, modifications, and alternatives.

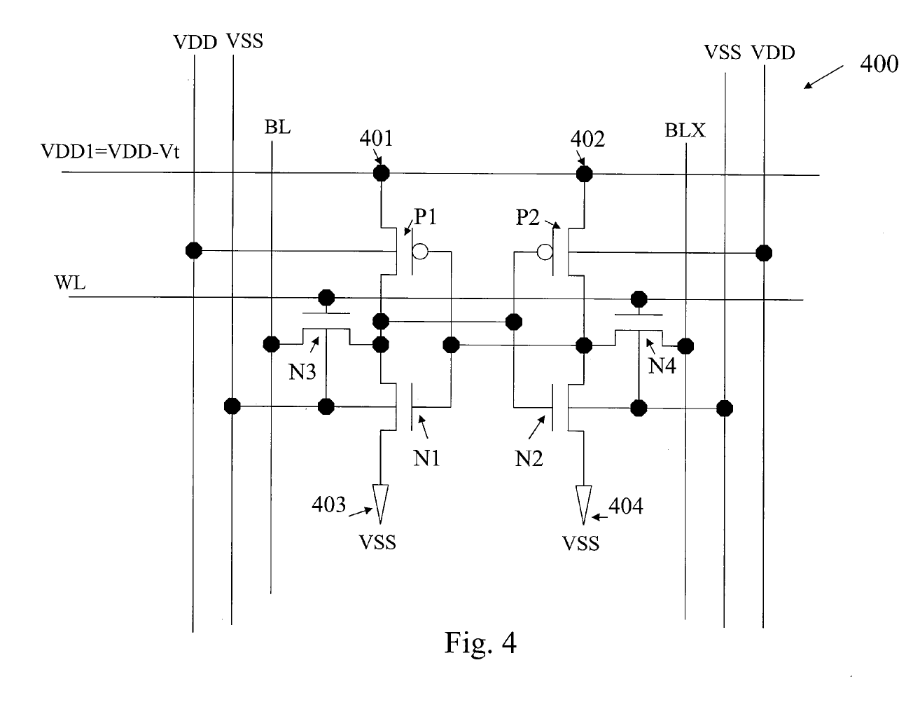

FIG. 4 is a simplified schematic circuit diagram of an SRAM memory cell 400 according to an embodiment of the present invention. This diagram is merely an example, which should not unduly limit the scope of the claims herein. One of ordinary skill in the art would recognize other variations, modifications, and alternatives. As shown, SRAM memory cell 400 includes six transistors. A left branch includes PMOS transistor P1 and NMOS transistor N1 are connected in series. P1 is a load device and N1 is a drive device. Similarly, a right branch includes PMOS transistor P2 and NMOS transistor N2 are connected in series. P2 is a load device and N2 is a drive device. The left branch and right branch are cross coupled, i.e. the input terminal of the left branch (gate terminals of P1 and N1) is connected to the output terminal of the right branch (the drain terminals of P2 and N2). Similar, the input terminal of the right branch (gate terminals of P2 and N2) is connected to the output terminal of the left branch (the drain terminals of P1 and N1). NMOS transistors N3 and N4 are selection transistors which connect the outputs of the memory cell to the bit lines BL and BLX, in response to signals at the word line WL. Memory cell 400 also includes power voltage supplies VDD and VDD1, and ground voltage supply VSS. In a particular example, the ground terminals 403 and 404 of memory cell 400, which are the source terminals of N1 and N2, respectively, are connected to a ground voltage supply VSS. When memory cell 400 is unselected, a power supply voltage of VDD1, which is equal to VDD−Vt, is applied to the power terminals 401 and 402 of the memory cell, which are the source terminals of transistors P1 and P2. The standby current of memory cell 400 is reduced with the lower power supply VDD1. When memory cell 400 is selected, a power supply of VDD will be applied to the power terminals of memory cell 400. Of course, there can be other variations, modifications, and alternatives.

In a specific embodiment, SRAM cell 400 is a CMOS SRAM cell including PMOS load devices 401 and 402 and NMOS drive devices 403 and 404. In some embodiments, the load devices can be NMOS transistors. In other embodiment, the load devices can be resistors. In alternative embodiments, the drive devices 402 and 404 can be PMOS transistors. Dependent upon the embodiments, memory cell 400 can be a DRAM cell, a non-volatile memory cell, or a read-only memory (ROM) cell. Memory cell 400 can be a memory cell in a stand alone integrated circuit memory or an embedded memory. Of course, there can be other variations, modifications, and alternatives.

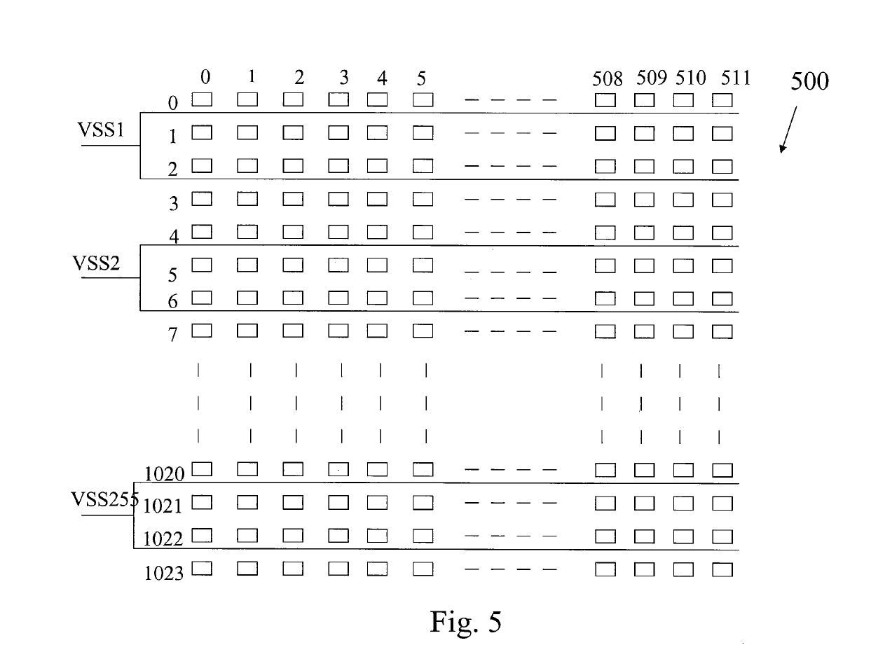

FIG. 5 is a simplified schematic diagram of an SRAM array 500 according to another embodiment of the present invention. This diagram is merely an example, which should not unduly limit the scope of the claims herein. One of ordinary skill in the art would recognize other variations, modifications, and alternatives. As shown, memory device 500 includes memory cells arranged in 1024 rows and 512 columns. In a specific embodiment, every four rows of memory cells share a ground voltage supply source. For example, rows 0-3 receive ground voltage supply from ground voltage supply source VSS via two ground voltage lines branched off from VSS1. Similarly, rows 1020-10233 receive ground voltage supply from ground voltage supply source VSS via two ground voltage lines branched off from VSS255. In an embodiment, four rows at a time are selected for a memory operation, such as read or write. The ground voltage supply voltage is kept to a low voltage, e.g. 0 volts, for these selected rows. The ground voltage supply voltage is maintained at a higher voltage, e.g. 0.3 volts, for unselected rows. Reduction in memory array standby current can be achieved by embodiments of the present invention. Of course, there can be other variations, modifications, and alternatives.

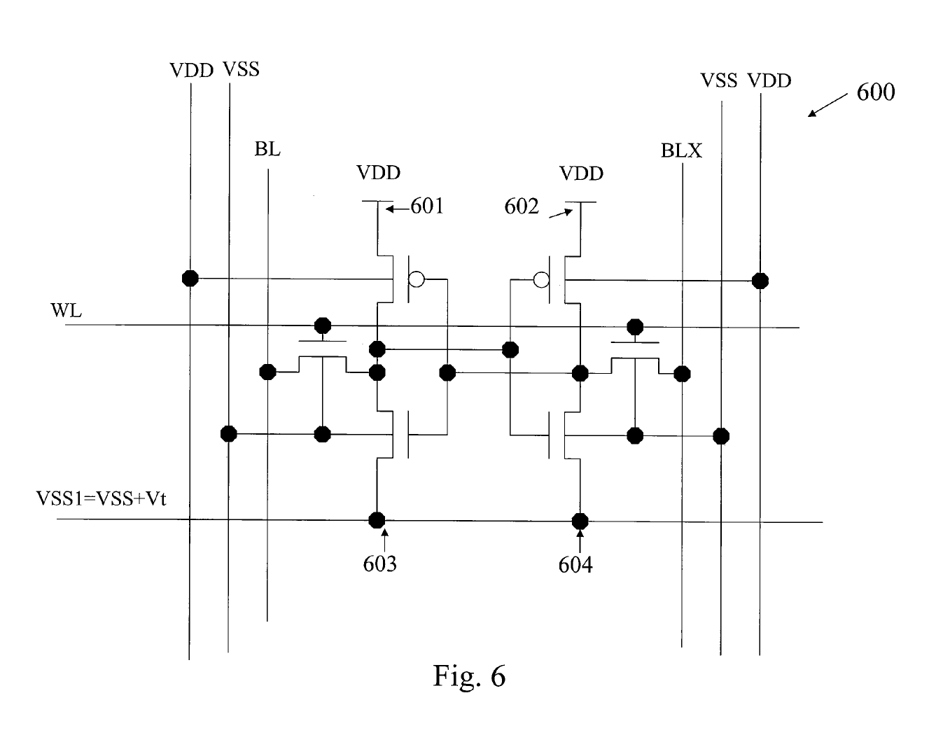

FIG. 6 is a simplified schematic circuit diagram of an SRAM memory cell 600 according to another embodiment of the present invention. This diagram is merely an example, which should not unduly limit the scope of the claims herein. One of ordinary skill in the art would recognize other variations, modifications, and alternatives. As shown, SRAM memory cell 600 includes six transistors, similar to memory cell 400 in FIG. 4. Memory cell 600 also includes power voltage supply VDD, and ground voltage supplies VSS and VSS1. In a particular example, the ground terminals 603 and 604 of memory cell 600 are connected to a ground voltage supply VSS1=VSS+Vt, when memory cell 400 is unselected. A ground voltage supply voltage of VSS is applied to the ground terminals 603 and 604, when memory cell 600 is selected. The standby current of memory cell 600 is reduced. Of course, there can be other variations, modifications, and alternatives.

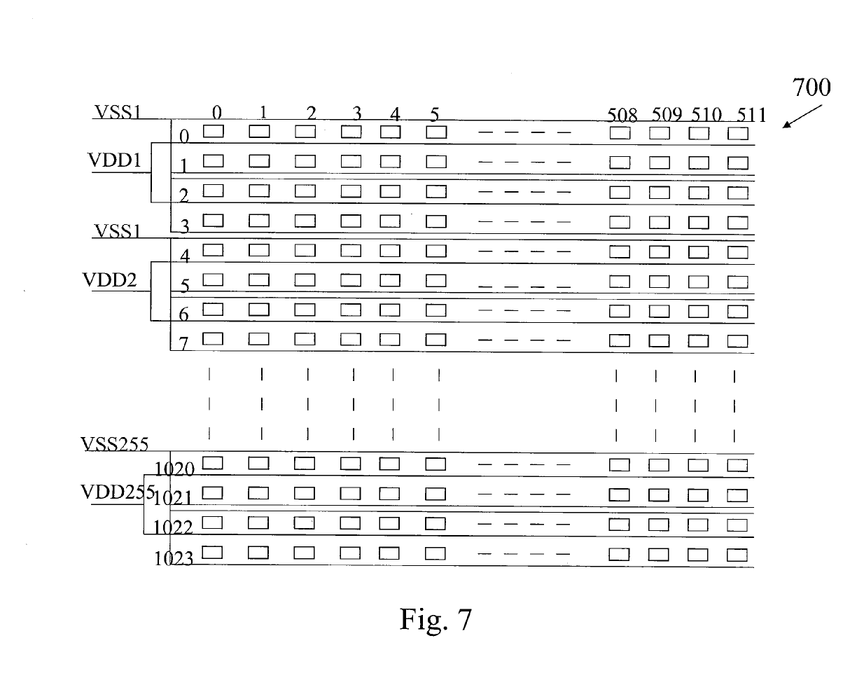

FIG. 7 is a simplified schematic diagram of an SRAM array according to an alternative embodiment of the present invention. This diagram is merely an example, which should not unduly limit the scope of the claims herein. One of ordinary skill in the art would recognize other variations, modifications, and alternatives. As shown, memory device 700 includes memory cells arranged in 1024 rows and 512 columns. In a specific embodiment, every four rows of memory cells share a power voltage supply source. For example, rows 0-3 receive power supply from power voltage supply source VDD via two power lines branched off from VDD1. Similarly, rows 1020-10233 receive power voltage supply from power supply source VDD via two power lines branched off from VDD255. In a specific embodiment, every four rows of memory cells share a ground voltage supply source. For example, rows 0-3 receive ground voltage supply from ground voltage supply source VSS via ground voltage lines branched off from VSS1. Similarly, rows 1020-10233 receive ground voltage supply from ground voltage supply source VSS via ground voltage lines branched off from VSS255. In an embodiment, four rows at a time are selected for a memory operation, such as read or write. The unselected rows receive a lower power voltage supply and a higher ground voltage supply, as will be discussed below. Reduction in memory array standby current can be achieved by embodiments of the present invention. Of course, there can be other variations, modifications, and alternatives.

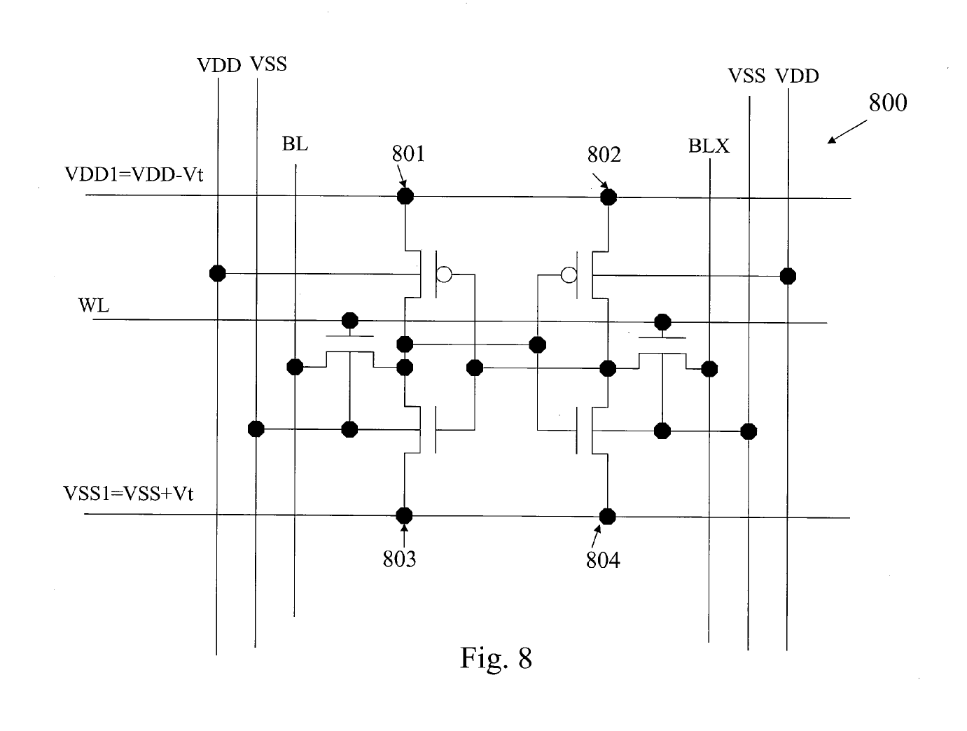

FIG. 8 is a simplified schematic circuit diagram of an SRAM memory cell according to an alternative embodiment of the present invention. This diagram is merely an example, which should not unduly limit the scope of the claims herein. One of ordinary skill in the art would recognize other variations, modifications, and alternatives. As shown, SRAM memory cell 800 includes six transistors, similar to memory cell 400 in FIG. 4. Memory cell 800 also includes power voltage supplies VDD and VDD1, and ground voltage supplies VSS and VSS1.

In a particular example, the ground terminals 803 and 804 of memory cell 800 are connected to a ground voltage supply VSS1=VSS+Vt, when memory cell 800 is unselected. A ground voltage supply voltage of VSS is applied to the ground terminals 803 and 804, when memory cell 800 is selected. As shown, the power terminals 801 and 802 of memory cell 800 are connected to a power voltage supply VDD1=VDD−Vt, when memory cell 800 is unselected. A power voltage supply voltage of VDD is applied to the ground terminals 801 and 802, when memory cell 800 is selected. The standby current of memory cell 800 is reduced. Of course, there can be other variations, modifications, and alternatives.

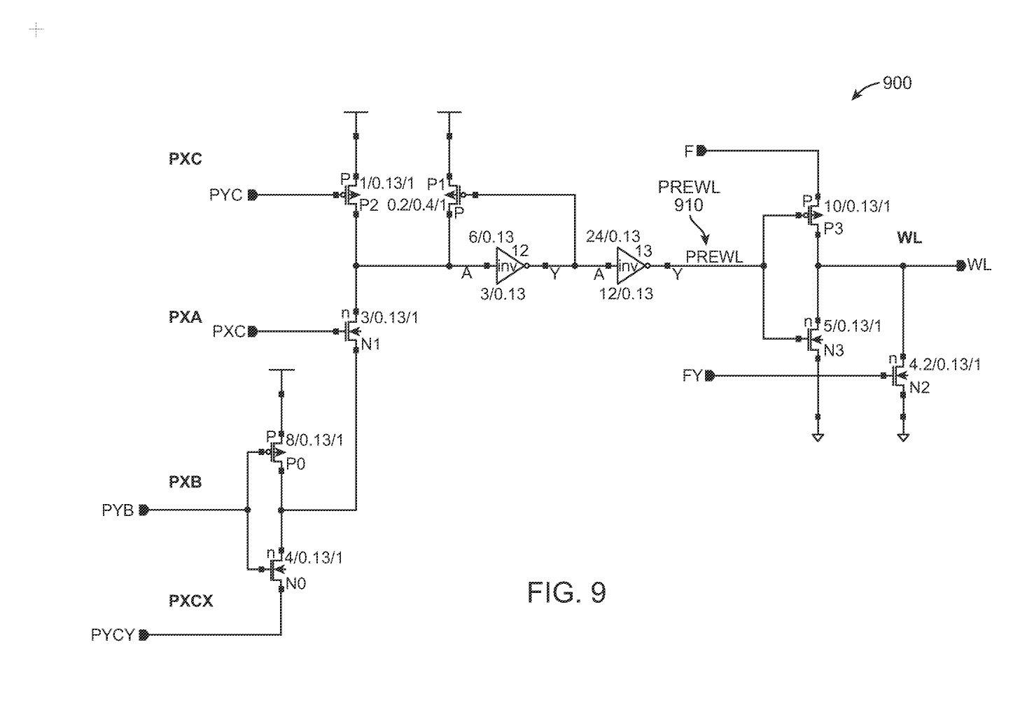

FIG. 9 is a simplified schematic circuit diagram of an address decoder circuit 900 for an SRAM device according to an embodiment of the present invention. This diagram is merely an example, which should not unduly limit the scope of the claims herein. One of ordinary skill in the art would recognize other variations, modifications, and alternatives. As shown, decoder circuit 900 includes four input signals, namely, F, PXA, PXB, and PXC. In a specific embodiment, an SRAM memory circuit includes 1024 rows of memory cells. An X-decoder uses a 10-bit address to select one of 1024 rows. In an embodiment, X addresses (bit A0 to A9) are divided into four groups: F (A0 to A1), PXA (A2 to A4), PXB (A5 to A7), and PXC (A8 to A9). For example, a first predecoder uses X address bits A0 and A1 to select one of four F signals. Similarly, a second predecoder uses X address bits A2-A4 to select one of eight PXA signals, a third predecoder uses X address bits A5-A7 to select one of eight PXB signals, and a fourth predecoder uses X address bits A8 and A9 to select one of four PXC signals. In an embodiment, each predecoder is implemented in NAND logic. In another embodiments, the predecoders can be designed with NAND and NOR logic. Depending on embodiments, the predecoders can be implemented using other conventional decoder techniques. One of ordinary skill in the art would recognize other variations, modifications, and alternatives.

In a specific embodiment, decode circuit 900 combines predecoded signals F, PXA,

PXB, and PXC to select one word line WL associated with one of 1024 rows. As shown in FIG. 9, decoder circuit 900 includes NMOS transistors N0 and N1, PMOS transistors P0, P1, and P2, and Invertors I2 and I3. Input signal PXC is electrically connected to P2. Input signal PXA is electrically connected to N1. Input signal PXB is electrically connected to N0 and P0. Input signal PXCX, which is derived from PXC, is electrically connected to N0. The drain terminals of N0 and P0 are electrically connected to a source terminal of N1. The drain terminals of N1 and P2 are electrically connected to a drain terminal of P1 and also electrically connected to inverter I2. The output of inverter I2 feeds back to a gate terminal of P1. The output of inverter I2 also feeds to inverter I3. A PREWL signal 910 is provided at the output of inverter I3. Although the above has been shown using a selected group of components for the decoder circuit, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification and more particularly below.

Referring to FIG. 9, according to a specific embodiment, only when PXA, PXB, PXC, and PXCX are high, high, high, low, respectively, will the corresponding PREWL signal be high. In an embodiment, each PREWEL signal selects four word lines. An F predecoder, which includes X Address bits A0 and A1, then selects one of the four word lines. For example, in decode circuit 900, the F and FX (inverse of F) signals and the PREWEL signal 910 are used to select word line WL. In a specific embodiment of the invention, the PREWL signal is used to select four rows of a memory array for power voltage allocation as discussed above for reducing cell leakage current and memory array standby current. In some embodiments, the PREWL signal can be used to in ground voltage selection, or for both power voltage and ground voltage selections. Therefore, according to embodiments of the present invention, selective application of power and ground voltage can be implemented using existing decoder circuitry with minimum modification to an SRAM circuit. Of course, one of ordinary skill in the art would recognize other variations, modifications, and alternatives.

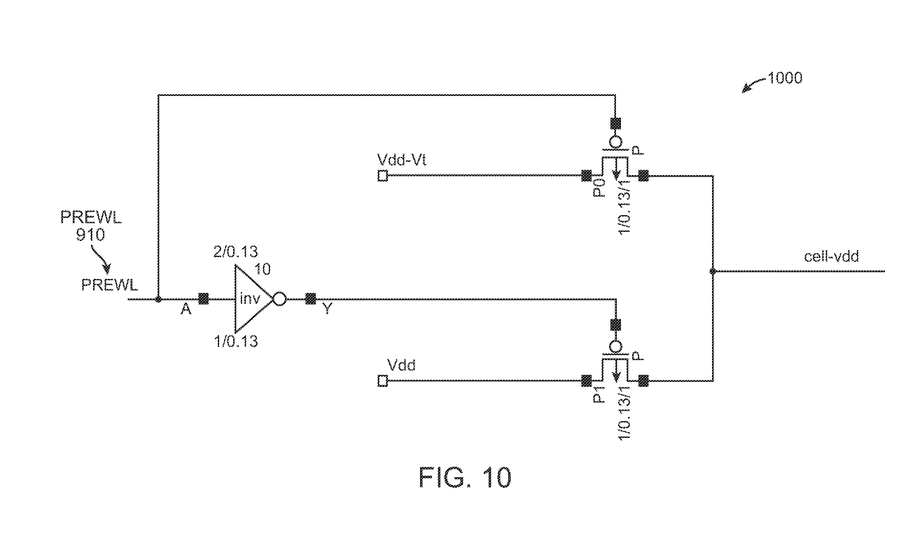

FIG. 10 is a simplified schematic circuit diagram of a power line decoder circuit 1000 for an SRAM according to an embodiment of the present invention. This diagram is merely an example, which should not unduly limit the scope of the claims herein. One of ordinary skill in the art would recognize other variations, modifications, and alternatives. In a specific embodiment of the invention, two VDD power rings are used around a memory array. The first power ring supplies 1.2V to active rows, and the other supplies 0.9V to inactive rows. As shown in FIG. 10, input signal PREWL 910 is electrically connected to a gate terminal of PMOS transistor P0, which is positioned between input voltage source Vdd−Vt and power voltage line cell1-Vdd. Also shown in FIG. 10, input signal PREWL 910 is first inverted by inverter I0 and is then electrically connected to a gate terminal of PMOS transistor P1, which is positioned between input voltage source Vdd and power voltage line cell-Vdd. In a specific embodiment, when the PREWL is high, power voltage supply Vdd is applied to cell-Vdd. When the PREWL is low, power voltage supply Vdd−Vt is applied to cell-Vdd. As discussed above, in a specific embodiment, signal PREWEL selects four word lines. Therefore, four word lines will receive full power supply voltage Vdd. The word lines not selected by signal PREWEL 910 will receive the reduced power voltage Vdd−Vt. However circuit 1000 is merely an example. Although the above has been shown using a selected group of components for power line decoder circuit 1000, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification and more particularly below.

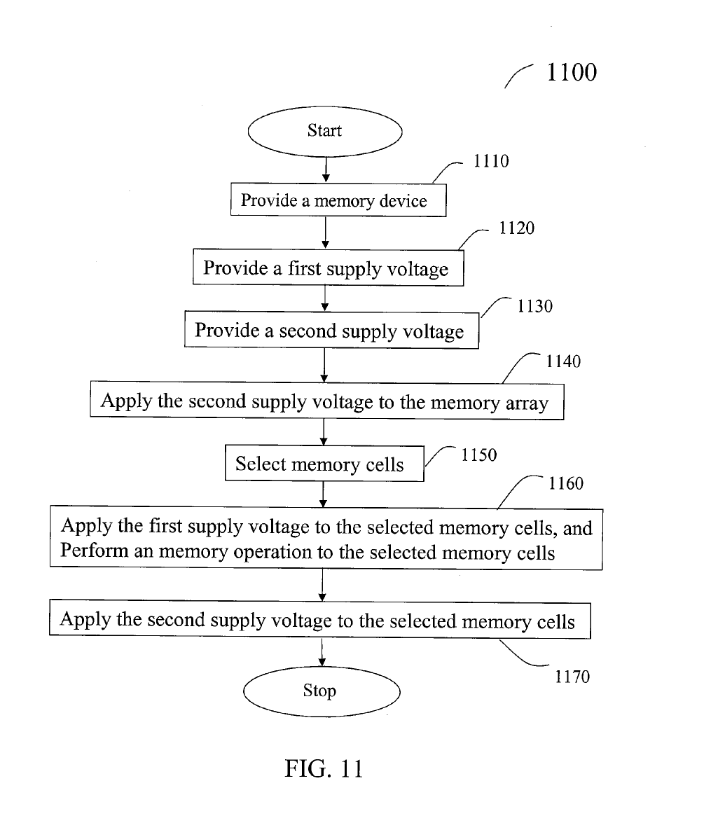

FIG. 11 is a simplified flowchart diagram 1100 of a method for providing voltage supply to an integrated circuit memory device according to an embodiment of the present invention. This diagram is merely an example, which should not unduly limit the scope of the claims herein. One of ordinary skill in the art would recognize many variations, alternatives, and modifications. According to a specific embodiment, the method can be briefly outlined as follows:

1. (Step 1110) Provide an integrated circuit memory device. The integrated circuit memory device includes a first plurality of memory cells. Preferably, each of the first plurality of memory cells include a power terminal and a ground terminal;

2. (Step 1120) Provide first power voltage supply. The first power voltage is associated with a power supply;

3. (Step 1130) Provide a second supply voltage lower than the first supply voltage;

4. (Step 1140) Apply the second supply voltage to the memory array;

5. (Step 1150) Select a second plurality of memory cells from the first plurality of memory cells. Preferably, the second plurality of memory cells includes a smaller number of memory cells than the first plurality of memory cells;

6. (Step 1160) Apply the first supply voltage to the power terminal of each of the selected memory cells to maintain an operating speed of the selected memory cells;

7. (Step 1170) Perform an memory operation to the selected memory cells; and

8. (Step 1180) Apply the second power voltage to the power terminal of each of the unselected memory cells, whereby power consumption in the unselected memory cells is reduced.

The above sequence of steps provides a method for providing voltage supply to an integrated circuit memory device according to an embodiment of the present invention. As shown, the method uses a combination of steps including a way of selectively lowering power supply voltage to unselected cells in a memory array while maintaining full power supply to the selected memory cells. Merely by way of example, the invention has been applied to SRAM devices for providing low power consumption while maintaining high memory speed. Other alternatives can also be provided where steps are added, one or more steps are removed, or one or more steps are provided in a different sequence without departing from the scope of the claims herein.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method for providing a voltage supply in an integrated circuit memory device, the method comprising:
providing an integrated circuit memory device, the integrated circuit memory device including a first plurality of memory cells, each of the first plurality of memory cells including a power terminal and a ground terminal;
providing a first power voltage, the first power voltage being associated with a power supply;
providing a second power voltage, the second power voltage being lower than the first power voltage in magnitude;
selecting a second plurality of memory cells from the first plurality of memory cells, the first plurality of memory cells including the second plurality of memory cells and a third plurality of memory cells, the third plurality of memory cells being unselected;
providing the first power voltage to the power terminal of each of the second plurality of memory cells;
providing the second power voltage to the power terminal of each of the third plurality of memory cells, the second power voltage being lower than the first power voltage in magnitude; and
performing at least a read operation and/or a write operation to at least one of the second plurality of memory cells.

2. The method of claim 1, further comprising:
providing a first ground voltage;
providing a second ground voltage, the second ground voltage being higher than the first ground voltage;
supplying the first ground voltage to the ground terminal of each of the selected memory cells; and
supplying the second ground voltage to the ground terminal of each of the unselected memory cells.

3. The method of claim 1, wherein each of the memory cells is an SRAM memory cell.

4. The method of claim 1, wherein each of the memory cells comprises a first and second cross-coupled branches, each branch further including a load device and a drive transistor connected in series.

5. The method of claim 4, where in the power terminal of each memory cell is electrically connected to the load device and the ground terminal is electrically connected to the drive transistor.

6. The method of claim 4, wherein the load device is a PMOS transistor and the drive transistor is an NMOS transistor.

7. The method of claim 4, wherein the load device is an NMOS transistor and the drive transistor is an NMOS transistor.

8. The method of claim 4, wherein the load device is a resistor and the drive transistor is an NMOS transistor.

9. The method of claim 1, wherein the first power voltage is about 1.2 volts.

10. The method of claim 1, wherein the second power voltage is about 0.9 volts.

11. The method of claim 2, wherein the first ground voltage is about 0 volts.

12. The method of claim 2, wherein the second ground voltage is about 0.3 volts.

13. The method of claim 1, wherein providing the second power voltage further includes providing a level-shifting transistor and lowering the first power voltage by approximately a threshold voltage of the level-shifting transistor.

14. The method of claim 1, wherein providing the second power voltage further includes providing a source follower circuit.

15. The method of claim 1 wherein selecting the second plurality of memory cells further includes:
providing a word line in the memory device, the word line being coupled to at least a memory cell; and
selecting the memory cells coupled to the word line.

16. The method of claim 1 wherein selecting the second plurality of memory cells further includes:
providing a plurality of word line in the memory device, each word line being coupled to at least a memory cell;
providing a word line pre-decoder for selecting a second plurality of word lines; and
selecting the memory cells coupled to the second plurality of word lines.

17. The method of claim 16, wherein the second plurality of word lines includes four word lines.

18. A method for providing a voltage supply in a memory device, the method comprising:
providing an integrated circuit memory device comprising a first plurality of memory cells, each memory cell including a power terminal and a ground terminal;
providing a first ground voltage;
providing a second ground voltage, the second ground voltage being higher than the first ground voltage in magnitude;
selecting a second plurality of memory cells from the first plurality of memory cells, the first plurality of memory cells including the second plurality of memory cells and a third plurality of memory cells, the third plurality of memory cells being unselected;
providing the first ground voltage to the ground terminal of each of the second plurality of memory cells; and
providing the second ground voltage to the ground terminal of each of the third plurality of memory cells, the second ground voltage being higher than the first ground voltage in magnitude;
performing at least a read operation and/or a write operation to at least one of the second plurality of memory cells.

19. An integrated circuit memory device, the memory device comprising:
a first plurality of memory cells, each memory cell including a power terminal;
a decoding circuit for at least selecting a second plurality of memory cells from the first plurality of memory cells and providing an output signal, the first plurality of memory cells including the second plurality of memory cells and a third plurality of memory cells, the third plurality of memory cells not being selected by the decoding circuit;
a switch circuit for supplying a first power voltage to the power terminal of each of the second plurality of memory cells and supplying a second power voltage to the power terminal of each of the third plurality of memory cells in response to the output signal of the decoding circuit;
wherein:
the first power voltage is provided by a first power supply;
the second power voltage is provided by a second power supply;
the second power voltage is lower than the first power voltage in magnitude.

20. The device of claim 19, wherein each of the first plurality of memory cells further including a ground terminal, the memory device further comprising:
a second switch circuit for supplying a first ground voltage to the ground terminal of each of the second plurality of memory cells and supplying a second ground voltage to the ground terminal of each of the third plurality of memory cells in response to the output signal of the decoding circuit;
wherein:
the first ground voltage is provided by a third power supply;
the second ground voltage is provided by a fourth power supply;
the second ground voltage is higher than the first ground voltage in magnitude.

21. The device of claim 20, wherein the first ground voltage is about 0 volts.

22. The device of claim 20, wherein the second ground voltage is about 0.3 volts.

23. The device of claim 19, wherein each of the memory cells is an SRAM memory cell.

24. The device of claim 19, wherein each of the memory cells comprises a first and second cross-coupled branches, each branch further including a load device and a drive transistor connected in series.

25. The device of claim 24, wherein the power terminal of each memory cell is electrically connected to the load devices and the ground terminal is electrically connected to the drive transistors.

26. The device of claim 24, wherein the load device is a PMOS transistor and the drive transistor is an NMOS transistor.

27. The device of claim 24, wherein the load device is an NMOS transistor and the drive transistor is an NMOS transistor.

28. The device of claim 24, wherein the load device is a resistor and the drive transistor is an NMOS transistor.

29. The device of claim 19, wherein the first power voltage is about 1.2 volts.

30. The device of claim 19, wherein the second power voltage is about 0.9 volts.

31. The device of claim 19, wherein the second power supply further includes a level-shifting transistor for lowering the first power voltage by about a threshold voltage of the level-shifting transistor.

32. The device of claim 19, wherein the second power supply further includes a source follower circuit.

33. The device of claim 19, further comprising:
a first plurality of word lines, each of the word lines being coupled to at least a memory cell; and
an input circuit for receiving an address signal;
wherein the decoding circuit selects a second plurality of word lines from the first plurality of word lines in response to the address signal.

34. The device of claim 33, wherein the second plurality of word lines includes one word line.

35. The device of claim 33, wherein the second plurality of word lines includes four word lines.
